(19) United States
(12) Patent Application Publication
(10) Pub. No.: US 2010/0034232 A1
(43) Pub. Date: Feb. 11, 2010

(54) ELECTRICALLY PUMPED ND3+ DOPED SOLID LASER

(75) Inventors: Fabrice Gourbilleau, Houlgate (FR); David Bréard, Soliers (FR); Richard Rizk, Caen (FR); Jean-Louis Doualan, Rots (FR)

Correspondence Address: IP GROUP OF DLA PIPER LLP (US), ONE LIBERTY PLACE, 1650 MARKET ST, SUITE 4900, PHILADELPHIA, PA, 19103, US

(73) Assignee: Centre National de la Recherche Scientifique-CNRS

(21) Appl. No.: 12/094,414

(22) PCT Filed: Nov. 21, 2006
(86) PCT No.: PCT/FR06/02558

§ 371 Date: Oct. 21, 2009

Related U.S. Application Data
(60) Provisional application No. 60/738,500, filed on Nov. 21, 2005.

(51) Int. Cl. H01S 5/30; H01L 33/00; H01L 21/04

(52) U.S. Cl. 372/50.11; 438/45; 438/770; 372/50.22; 257/E33.002; 977/773; 257/E21.04

(57) ABSTRACT

A laser amplification structure comprising an active medium and at least two electrodes disposed on either side of the active medium, the active medium comprising a first layer of a silicon oxide doped with rare earth ions, wherein the first silicon layer is co-doped with silicon nanograins and rare earth ions.

### RELATED APPLICATIONS

This is a §371 of International Application No. PCT/FR2006/002558, with an international filing date of Nov. 21, 2006 (WO 2007/057580 A2, published May 24, 2007), which claims priority of U.S. Provisional Application No. 60/738,500, filed Nov. 21, 2005, incorporated herein by reference.

### TECHNICAL FIELD

This disclosure relates to the field of solid-state lasers and, more specifically, to laser cavities doped with rare earth ions.

### BACKGROUND

The laser market is mainly dominated by laser diodes and lasers based on insulating materials (glass and crystal) doped by rare earths or transition metals.

Laser diodes consist mainly of a diode with a semi-conductor which aims to produce a light beam. Pumping is carried out with the help of an electrical current that enriches the generating medium with holes on one side and electrons on the other. The light is produced at the junction by recombining the holes and the electrons. This type of laser does not have any cavity mirrors. In laser diodes, the population inversion required to obtain the laser effect is made possible by means of electrical excitation improving the compactness of such systems. However, these systems are different from solid-state lasers, in terms of operation or structures and, consequently, the physical problems that arise.

Solid-state lasers use solid-state media, such as crystal or glass as a medium for photon emission. Crystal or glass is only the gain medium and is doped by at least one ion which is the laser medium (active medium: medium where the laser effects take place, which is to say the phenomena of exciting and de-exciting doping elements for light emission). Among solid-state lasers, the best known and one of the most common is YAG:Nd³⁺. The insulating materials (crystal and glass) doped by active ions require optical pumping by a lamp or a laser diode, thus limiting their integration. On the other hand, their characteristics are different from and complement the laser diodes (brief, high-energy pulses, strong brilliance, spectral tunability, strong power of light emission, etc.).

Active media are also used in similar domains such as doped fibers, waveguide amplifiers, etc.

The field of rare earth doped fibers has seen considerable development with the creation of very-high power laser. The fiber provides great flexibility of use, but does not allow laser integration.

For integrated systems in the form of thin guiding layers doped by active ions, the effort relates mainly to telecom amplifiers doped with Er³⁺ and Tm³⁺ at around 1.5 μm. Extensive work has also been conducted regarding the production of laser in thin guiding layers, for which high power levels can be obtained. Such systems are described, for example, in patent applications WO-03/065093 and US-2005/0195472. In WO-03/065093, a silicon oxide wave-guide co-doped with nanoclusters (nanograins) of silicon Si and rare earth atoms absorbs visible light but not infrared emissions. Based on this principle, an optical pumping source is placed above the waveguide. The pumping light injected in the waveguide excites the silicon nanograins (by electron-hole combinations), which in turn excite the rare earth elements. Such an energy transfer between the silicon nanograins and the rare earth elements has been suggested in the publication entitled “The Nd-nanocluster coupling strength and its effect in excitation/de-excitation of Nd3+luminescence in Nd₋doped silicon-rich silicon oxide” (Seo et at. Applied Physics Letters, Volume 83, Number 14, 6 Oct. 2003) and increased effectiveness (factor of several tens or even one hundred) is obtained. An optical input signal is then amplified in the waveguide using the energy generated by the rare earth elements and comes out in the form of an amplified optical output signal.

This system, like all systems including silicon nanograins, requires the combination of a laser diode for optical pumping and a doped active medium, which limits integration.

It could therefore be helpful to promote the integration of solid-state lasers in more complex systems.

It could also be helpful to provide the most compact solid-state lasers possible.

The presence of laser diodes for optical pumping also implies a waste of energy due to their efficiency.

It could further be helpful to reduce the power consumption of solid-state lasers and therefore to increase the efficiency of these systems.

Laser diodes, although inexpensive, still require an economic expenditure when manufacturing the solid-state laser system.

It could still further be helpful to reduce the cost of manufacturing solid-state lasers without, however, making them more complex to manufacture.

In US-2005/0195472, an optical amplifier consists of a waveguide made from silicon doped with Erbium ions, the waveguide being powered by pumping energy which can be optical or electrical using two electrodes arranged on opposing walls of the waveguide, or by Raman scattering. In the embodiment with electrical pumping, the Erbium ions are excited by the electrical field applied between the two electrodes. However, such direct excitation does not work in practice, since the Erbium ions have low sensitivity to the electrical field, the only possibility for direct excitation of active Erbium ions being photon absorption by this ion (which is the opposite of electrical excitation), and the system therefore consumes a lot of energy to obtain a sufficient number of excited ions.

It could therefore be helpful to supply an electrical pumping laser solution which allows easier excitation of the doping ions, in particular a solution that consumes less energy with improved efficiency.

It is also noted that the operation of these similar systems (waveguide amplifier, laser fiber, etc.) depends to a great extent on the input light signal, which is amplified. In contrast, the solid-state lasers to which our disclosure relates do not require the use of input light signals to emit the output signal.

### SUMMARY

We provide a laser amplification structure including an active medium and at least two electrodes disposed on either side of the active medium, the active medium including a first layer of a silicon oxide doped with rare earth ions, wherein the first silicon layer is co-doped with silicon nanograins and rare earth ions.

We also provide an optical laser including an optical cavity equipped with the amplification structure and an electric current generator connected to the electrodes.

We further provide a method of manufacturing a laser amplification structure, including depositing an active medium including depositing a layer of a silicon oxide co-doped with silicon nanograins and rare earth ions on a substrate, and depositing electrodes on either side of the active medium.

### BRIEF DESCRIPTION OF THE DRAWINGS

The disclosure will be understood better from the following detailed description and the appended figures wherein:

FIG. 1 is a diagrammatic representation of a target-cathode and the substrate-anode within the depositing frame in the configuration of the deposits of co-doped thin layers;

FIG. 2 is a graphic showing the absorption spectrum of the Nd³⁺ ion in a SiO₂—Nd film deposited by magnetron sputtering;

FIG. 3 is a graphic showing the influence of the hydrogen ration in the plasma on the emission intensity of the Nd³⁺ ion in films annealed at 900° C.;

FIG. 4 is a graphic showing the PL intensity of a film manufactured with 80% of H₂ in the plasma and annealed under various conditions;

FIG. 5 is a diagrammatic representation of the two target-cathodes and the substrate-anode within the depositing frame for a multilayer deposition; and

FIGS. 6 and 7 show multilayer embodiments.

### DETAILED DESCRIPTION

We use silicon nanograins in the active medium, nanograins which are sensitive to an electrical field passing through the active medium. Our disclosure therefore relies on electrical excitation of active ions by means of a semiconductor.

For this purpose, we provide a laser amplification structure comprising an active medium and at least two electrodes arranged on either side of the active medium, the active medium comprising a first layer of a silicon oxide co-doped with silicon nanograins and rare earth ions (hereinafter also referred to as “co-doped layer”). In practice, the electrodes are connected to an electrical power supply so that, when in use, an electrical current runs through the first layer to excite the silicon nanograins. This laser amplification structure is electrically excitable.

The silicon nanograins have been seen to be sensitive to the electrical current running through the active medium. Thus, the silicon nanograins are excited by the electrical current and then transfer their excitation energy to the rare earth ions as explained in the aforementioned publication by Seo et al. Traditional mechanisms for stimulated laser emission are then applied to emit electromagnetic radiation by de-excitation of the rare earth ions. It is noted at this point that the silicon nanograins act as electrical dopants capable of transmitting their energy to other dopants.

Such a structure therefore makes it possible to do without a secondary light source (pumping laser diode).

One application of these structures is photonics, in which they are generally integrated in semiconductor circuits.

For this purpose, it is provided for the first layer to be a thin layer in the semiconductor sense, which is to say a layer with a thickness less than or substantially equal to one micrometer (1 μm), generally deposited on a considerably thicker substrate to benefit from the mechanical properties of the latter. In this way, the structure obtained offers considerable compactness, which allows easy integration in devices or integrated circuits. In one aspect, the active medium consists only of this co-doped thin layer and therefore has a thickness of substantially one micrometer.

The dimensions of the nanograins compared with the thickness of a layer of silicon oxide make it delicate to create a homogenous co-doped layer.

To solve this problem, it is possible to use multilayer structures that alternate co-doped thin layers and non-doped thin layers with rare earth ions (and possibly with nanograins).

For this purpose, it is provided for the active medium to comprise, in addition, a thin layer of silicon oxide not doped with rare earth ions on which the first layer is deposited. It is also provided for the active medium to comprise a second layer of a silicon oxide doped with silicon nanograins and rare earth ions on which the non-doped layer is deposited. In this configuration, it is necessary for the non-doped layer to be thin because, as it constitutes an insulating layer, it must guarantee the tunnel effect necessary for the circulation of electrical current between two co-doped layers. As an example, a thickness equal to or less than 5 nm is recommended for the non-doped layer.

Our disclosure is not limited to an active medium made up of two co-doped layers and one non-doped layer, but also provides for active media having a large number of co-doped layers separated two-by-two by a non-doped layer. Multilayer structures are provided which comprise several tens or even hundreds of layers and, in exceptional cases, several thousands of layers. A multilayer active medium is preferably chosen in which the two outer layers (top and bottom) are by nature co-doped with Si nanograins and rare earth ions. The active medium thus formed comprises all the co-doped layers (therefore capable of generating a light wave).

In a multilayer embodiment, the electrodes are positioned parallel to the layers, each electrode covering all or part of the surface of the top and bottom layers (outer layers) of the active medium. The bottom electrode can be either directly in contact with the active medium, which is to say between the latter and the growth substrate, or positioned on the underside of the substrate, the latter allowing electrical conduction.

Commonly used active media have a thickness of several millimeters. The size of the samples can be changed to several hundred micrometers, either to improve heat dissipation (thin disk) or increase the compactness (microchip). The Nd³⁺ ion is well suited for microchip devices, with its larger effective absorption and emission sections.

Also in the design of facilitated integration of the structure, the active layer of the structure has a thickness of the order of several μm, preferably around one micrometer according to the current injection characteristics and the indices for guiding the light in the layer. In particular, when a single co-doped thin layer is used in the active medium, the thickness is chosen to have a thickness of the order of one μm or less. It should be remembered that the active layer in this case is the active medium made up of the multilayer assembly (co-doped layers, non-doped layers).

With a view to optimizing the energy transfer between the silicon nanograins and the rare earth ions, we provide for the co-doped layer to have a nanocrystalline or amorphous structure, the average distance separating a rare earth ion from a Si nanograin in the active medium being less than or equal to 0.4 nm.

The amplification structure is implemented in lasers as an element of the resonant optical cavity. For this purpose it is equipped with reflecting surfaces, such as mirrors. The active medium preferably comprises Bragg gratings arranged substantially perpendicular to the electrodes, the gratings being made from germanium Ge ions photoinscribed in the co-doped layer(s). To increase the effectiveness of the system, all the co-doped layers of the active medium comprise Bragg gratings, preferably aligned from one layer to the other. These gratings optically close off the optical cavity acting as mirrors for the electromagnetic emissions of excited rare earth dopant ions. It is recommended, preferably, to place them substantially directly below the end of the electrodes, and possibly beyond (towards the edges, at the ends of the guiding co-doped layers) when the electrodes only cover part of the surface of the active medium. In practice, two parallel Bragg gratings face each other on either side of the electrodes and delimit the laser optical cavity.

Preferably, one of the gratings is semi-reflecting. In the embodiment comprising only one co-doped layer, the two gratings are arranged, in this same layer, perpendicular to the top and bottom surfaces (in the thickness) of the layer.

Furthermore, one of the electrodes is made from gold (Au) which provides considerable electrical conductivity while minimizing energy losses. The other electrode can be made from a Ni—Cr alloy.

The electrodes may each comprise a conductive layer, for example, made from ITO (Indium-Tin-Oxide), respectively adjacent to one of the opposing faces of the active medium. The rare earth ions may also be chosen from the following: Nd³⁺, Yb³⁺, Er³⁺, Tm³⁺ and Ho³⁺.

In particular, Nd³⁺ has rapidly imposed itself as the main active ion for laser equipment. The success of YAG:Nd³⁺ has made the transition to 1,064 μm a standard in terms of laser emission for applications in which wavelength is not the criteria for selection. Among the other rare earth ions, we should mention Yb³⁺, which has emission in the same wavelength range. For a long time, optical pumping of the Nd³⁺ ion was carried out by lamps with great pumping efficiency since this ion has numerous levels of energy above the emitting laser level, which absorb a large part of the light emitted by the lamps. The development, during the 1980s, of AlGaAs diodes emitting at around 800 nm, requires the gradual replacement of Nd³⁺ lasers using lamp pumping with lasers using laser diode pumping. The Nd³⁺ ion, used mainly for its emission at around 1.06 μm is of the type comprising a laser system with four levels in which the population inversion is very easy to obtain since the laser terminal level (⁴I_{1 1/2}) has a life cycle several orders of magnitude shorter than the laser emitter level (⁴F_{3/2}), while most of the other ions (Yb³⁺, Er³⁺, etc.) are systems with almost three levels. A preferred structure is therefore provided using Nd³⁺ ions. For these “other” ions, the laser terminal level is thermally populated since it is close to the fundamental level of the ion, which requires more considerable pumping to perform the population inversion required to reach the laser threshold. The advantage provided by using the Nd³⁺ dopant ion is thus that it reduces power consumption to achieve the desired pumping. In addition, it is necessary to optimize the length of the active medium to prevent reabsorption of the laser emission. The effective absorption and stimulated emission sections play a very important role. For the Nd³⁺ ion, these effective absorption and emission sections are much larger than for other ions, in particular Yb³⁺, for a given gain medium.

We also provide an optical laser comprising an optical laser cavity equipped with an amplification structure and an electric current generator connected to the electrodes. Precisely, the generator is arranged, when in use, to run an electrical current through the active medium to excite the silicon nanograins, in particular in the first layer. According to the previously mentioned mechanisms, the rare earth ions are excited in turn by energy transfer from the Si nanograins to them.

The lasers thus produced are as compact as laser diodes while providing additional functions such as very high-energy pulses, spectral purity and stability regardless of temperature or manufacturing conditions.

We also provide a method for manufacturing a laser amplification structure, comprising:
a first step of depositing an active medium including depositing a layer of a silicon oxide co-doped with silicon nanograins and rare earth ions on a substrate, and
a step of depositing electrodes, on either side of the active medium, possibly on at least one part of the co-doped layer.

Several alternatives are possible for depositing the electrodes. In a first alternative, it is provided to deposit a metal electrode on the side of the active layer (in this case the co-doped layer, but possibly the multilayer assembly mentioned at several points in the present description) opposite the substrate and another metal electrode on the reverse of the latter (substrate), if this is not an insulating obstacle which prevents electrical conduction in the active medium.

A second alternative provides for depositing a transparent conductor layer on the two opposing surfaces of the active layer, of the ITO (Indium-tin-oxide) type. In particular, it is possible to deposit an ITO layer on the substrate before depositing the active layers. Metal contacts can then be deposited on these transparent conductive layers to allow connection to a current generator. The assembly made up of the transparent conductive layer and the contact terminals forms an electrode used for electrical excitation of the co-doped active medium.

It is also provided for an electrode to be deposited prior to the step of depositing the active medium by depositing a conductive layer on the substrate, and by the fact that a second electrode is deposited after the step of depositing the active medium on the opposite surface of the active medium.

In one aspect, the depositing step is carried out by reactive magnetron co-sputtering of at least one target comprising a first silicon oxide material and a second rare earth material. It is possible for the second material to be arranged on one part of the target. In other words, it is provided to use several targets, each equipped with a single type of material in a confocal co-sputtering process.

During this deposition step, the substrate acts as an anode and the target acts as a cathode. By this mechanism, plasma is created between the anode and the cathode, allowing the detachment of silicon elements, oxides and rare earth elements, which condensate on the substrate.

Reactive magnetron co-sputtering processes are considerably well suited to the formation of thin layers. They therefore allow the production of almost-planar structures, which are therefore well suited for semiconductors and for the production of electrically excited planar lasers.

According to two variations, at least one target is a single silicon oxide target surmounted by a plurality of rare earth oxide wafers (variation 1), and at least one target comprises a silicon Si target, a target of the first silicon oxide SiO₂ material and a target of the second rare earth material (variation 2).

The second variation has the advantage of implementing normal co-sputtering of three parallel cathodes, limiting the interactions between the various elements of the target in the global sense (which are more difficult to control).

The nature of the plasma used during the co-sputtering step depends to a certain extent on the composition of the co-doped layer formed. Thus, it is provided for this co-sputtering step to be carried out in a vacuum enclosure comprising argon and/or hydrogen and/or nitrogen plasma. In the case of reactive sputtering, the presence of hydrogen makes it possible to reduce the silicon oxide to include a silicon excess (silicon nanograins) in the SiO₂ gain medium also deposited. The rare earth ions are introduced in the Si—SiO₂ composite by means of the plasma. For this purpose, it is provided for the hydrogen rate in the plasma to be comprised between 10% and 90%. This rate encourages, according to the deposition conditions (plasma pressure, substrate temperature, distance between electrodes, etc.), the formation of a larger or smaller amount of Si germs, and therefore the density of the nanoclusters inside the deposited layer.

Generally, a plasma containing hydrogen is used in the absence of a pure silicon target; this is the case in the hypothesis of a SiO₂ target surmounted by rare earth oxide wafers or in the hypothesis of two SiO₂ and Nd₂O₃ targets. In the latter hypothesis, a mix of Ar+H₂ is used to add silicon Si to the growing co-doped layer (for a single layer), or a mix of Ar+H₂ is used to add silicon Si to the co-doped layer enriched with nanoclusters and a pure argon plasma for the growing Silicon layer non-doped with rare earth ions.

On the other hand, if three targets —Si, SiO₂ and Nd₂O₃— are deposited, no presence of hydrogen is required since the target Si supplies the nanoclusters with Si without needing to reduce the SiO₂ silicon.

Another parameter to be taken into consideration is that of the surface of the target taken up by the rare earth material, which is preferably comprised between 3 and 30% of the total surface of the target depending on the rare earth ion in question. This parameter makes it possible to change the ratio of rare earth ions in the final deposit in relation to the silicon excess (nanograins). For example, in the case of the Erbium ion, the optimal surface is comprised between 23% and 26% while in the case of the Nd³⁺ ions, it should not exceed 12%.

With a view to obtaining Bragg gratings as mentioned above, it is provided, during the co-sputtering step, for the target also to be surmounted by at least one wafer containing germanium (Ge). Also by reactive magnetron co-sputtering, the germanium ions are extracted from the wafer and deposited in the layer being deposited. The germanium ions thus deposited are inscribed to form the gratings. Photoinscription is carried out using a UV laser. An interference pattern is projected on the part of the guide that contains Ge, inducing irradiated zones and non-irradiated zones thus forming the grating. The irradiation induces the formation of colored centers which modify the index of the medium. In this way, an alternation of zones with different indices is obtained, which plays the role of a mirror.

For this purpose, it may be provided not to place the germanium wafer until the right moment for the formation of the Bragg gratings, which is to say only when depositing the co-doped layers (since there is no light emission in the non-doped layers not provided with rare earth ions).

According to one alternative, it is provided to deposit Ge throughout the growing co-doped layer. The Ge ions are inactive from the point of view of the rare earth ions (for example Nd³⁺). Then, the grating is inscribed only in the desired zones (ends of the layers).

Furthermore, the molecular faults that can be created when depositing the layers must be repaired or reduced. To do this, the method also comprises a step of annealing the layer thus formed at a temperature comprised between 800 and 1100° C. during at least ten minutes.

The method may comprise a step of depositing a doped polycrystalline silicon layer N on the doped layer prior to depositing the electrodes.

To produce the aforementioned multilayer active media, the method can comprise in succession:
depositing a co-doped layer, and
a subsequent deposition step for forming a non-doped silicon oxide layer on the co-doped layer.

It is provided for the deposition of a co-doped layer to be a step of reactive magnetron co-sputtering of at least one target comprising a first silicon oxide material and a second rare earth material, the second material being arranged on one part of the target, and for the subsequent deposition step to be a step of reactive magnetron sputtering of a silicon oxide target in a vacuum enclosure comprising an argon plasma to form a non-doped silicon oxide layer on the co-doped layer.

Different cathodes are chosen for each of the co-sputtering and sputtering steps, since the reaction parameters are different.

More precisely, the method comprises a plurality of alternations of co-sputtering steps and sputtering steps to form a multilayer structure, the first and last steps performed being, preferably, co-sputtering steps for depositing co-doped layers, the electrode being deposited on top of the layer opposite the substrate in the structure (the other one being on the reverse of the substrate).

According to two alternatives, during the sputtering step:
the argon plasma is a pure argon plasma, making it possible to obtain a non-doped layer with no Si nanograins;
the plasma is enriched with hydrogen, so as to include an excess of Si in the non-doped insulating layer. This facilitates electrical conduction in the thin insulating layer and allows the tunnel effect.

Furthermore, the rare earth ions are of at least one type chosen from among the ions Nd³⁺, Yb³⁺, Er³⁺, Tm³⁺ and Ho³⁺.

Furthermore, it is also provided to manufacture a sliver guide to allow lateral guiding of the light. These sliver guides can be manufactured by etching once the layers have been deposited. Starting with the multilayer device, a sliver guide from several nm to several tens of nm is etched with the help of a mask. A suitable technique for this can be reactive ion etching (RIE).

We also provide an operating method of a laser comprising an optical cavity equipped with a laser amplification structure and an electrical current generator, the laser amplification structure comprising an active medium and at least two electrodes disposed on either side of the active medium, the active medium comprising a first layer of a silicon oxide is co-doped with silicon nanograins and rare earth ions, and the electrical current generator is connected to the electrodes, the method comprising a step of running an electric current through the active medium by applying a power supply to the terminals of the electrodes.

We also provide a use of a laser amplification structure comprising a layer of a silicon oxide co-doped with silicon nanograins and rare earth ions, electrically pumped as a laser amplifier. This use can be applied equally to a laser or a laser fiber.

The following example shows the mechanism and the optimization of the effective energy transfer between Si nanograins and the Nd³⁺ ion, for thin layers manufactured by reactive magnetron sputtering, therefore allowing the production of an electrically excited planar laser.

The confinement of the carriers (excitons) within the silicon nanograins inserted in a silica gain medium make it possible to obtain visible luminescence by electrical or optical excitation of such a composite system. Extensive work has been conducted regarding the study of silicon nanograins associated with the Er³⁺ ion to manufacture amplifiers in the field of wavelengths suitable for telecommunications (1.54 μm). An effective energy transfer exists between the nanograins and the rare earth, which can therefore emit with an intensity 100 times greater than that prevailing without the presence of nanograins.

A silica gain medium containing silicon nanograins associated with the Nd³⁺ ion is used to manufacture an integrated laser. In fact, the existence of a transfer has recently been proven between Si nanoclusters and the Nd³⁺ ion in layers manufactured by PECVD (plasma-enhanced chemical vapour deposition) assisted by ECR (electron cyclotron resonance) [Seo et al. Appl. Phys. Lett., 83, 2778 (2003); “The Nd-nanocluster coupling strength and its effect in excitation/de-excitation of Nd³⁺ luminescence in Nd-doped silicon-rich silicon oxide.”]. Our disclosure allows electrical excitation of the silicon nanograin which, transferring its energy to the Nd³⁺ ion, thus creates a population inversion between the two laser levels of this ion. A laser emission at around 1.1 μn, depending on the nature of the gain medium (material and dopants), is therefore obtained.

It is a case of manufacturing thin layers of a silica glass co-doped with neodymium and Si nanograins by reactive magnetron co-sputtering. These guiding layers produce, after etching and deposition of electrodes, an electrically excited laser system, which can emit at around 1.1 μm. This approach is compatible with silicon technology and is perfectly consistent with the current trend to manufacture easily integrated compact systems.

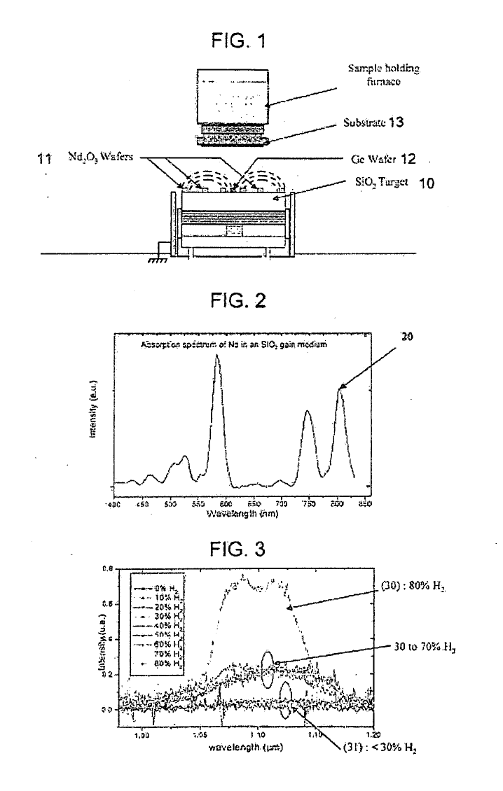

The reactive co-sputtering technique used, among others, to deposit thin layers, is diagrammatically represented in FIG. 1.

A pure silica target 10 is surmounted by a variable number of Nd₂O₃ (rare earth oxide) wafers 11 so as to modulate the concentration of Nd³⁺ ions included in the deposited layer, as well as pieces of Ge or GeO₂ 12 to allow an increase in the photosensitivity of the silicon by reducing its gap [see Nishi et al., Optics Lett., Vol. 20, issue 10, 1184 (1995); “Ultraviolet-radiation induced chemical reactions through one-and two-photon absorption processes in GeO₂—SiO₂ glasses”]. In this way, Bragg gratings, act as future mirrors for the optical cavity, are photoinscribed at the two ends of the silicon guide doped with Nd³⁺ ions and contain Si nanograins. The excess silicon included in the layer is obtained through the reactive nature of the plasma, which consists of a mix of ionised argon and hydrogen which sputter and interact with the SiO₂—Nd₂O₃—Ge compound. Bearing in mind the reducing nature of hydrogen with regard to oxygen, such a method results in an oxygen deficit in the layer and thus makes it possible to control the amount of excess silicon by modifying the partial pressure of the hydrogen. In addition to this parameter, the use of a reactive gas such as hydrogen leads to a phenomenon of selective etching of the growing layer, thus encouraging a multiplicity of nucleation sites for the Si nanograins. The resulting higher density of nanograins guarantees a higher coupling strength with the Nd³⁺ ions and thus a high proportion of optically active ions. The depositions take place at room temperature with a power varying between 50 W and 120 W and a total pressure of the gas not exceeding 6×10⁻² Torr. In this configuration, the ionization of the gases allows the elements to be removed from target and deposited on the substrate (anode) 13.

The post-deposition heat treatments are performed at between 800 and 1100° C. and, according to time, under a flow of pure Ar or N₂.

An absorption spectrum of the Nd³⁺ ion coming from a film of SiO₂—Nd (without the presence of excess silicon) manufactured by magnetron sputtering, is presented in FIG. 2. This spectrum highlights the presence of the strong absorption (20) of the Nd³⁺ ion at 800 nm, which makes it possible to foresee the energy transfer between the excited Si nanograins and the Nd³⁺ ion. In addition, it can be seen that the 488 nm line supplied by an Argon laser is a line with very low resonance for the Nd³⁺ ion, allowing this excitation wavelength to be used to highlight this energy transfer with the rare earth ion.

FIG. 3 shows the changes in photoluminescence intensity of the Nd³⁺ ion according to the hydrogen ratio r_{H}=P_{H2}/P_{H2}+P_{Ar}) in the plasma for thin films produced at an RF power of 60 W. It can be seen that the film deposited with the highest hydrogen ratio r_{H}=P_{H2}/P_{H2}+P_{Ar}) has the highest intensity (30) with a split emission peak. This is due to the maximum density of the Si nanograins acting as relays for exciting the Nd³⁺ ions, as already mentioned. The sensitizer role played by the Si nanograin is clearly shown with a considerable increase of the intensity of the films containing silicon compared with those produced with a pure (or almost pure) argon plasma (31) and which therefore contain little or no excess Si.

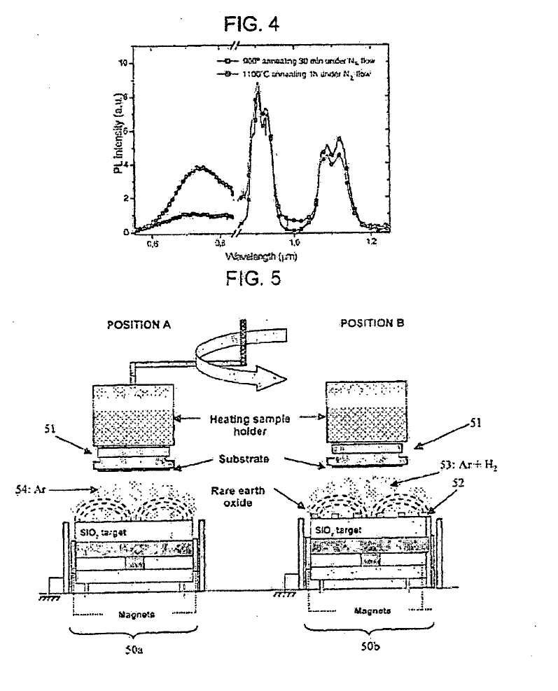

The effect of the heat treatment applied to the emission of the Nd³⁺ ion is presented in FIG. 4. The temperature increase considerably favors one of the emission peaks at the expense of the other while increasing its intensity by one order of magnitude.

The simple linear guide with or without cladding is obtained after etching and depositing electrodes to allow current injection. These electrodes (Al, Au, Al—Si alloy, etc.) are deposited all along the guide, as well as on the reverse of the substrate. The electrical excitation leads to the formation of an exciton within the Si nanograin which, by recombining, will either emit at 800 nm or transfer its energy to the Nd³⁺ ion located in the proximity, and therefore allow the emission of this rare earth element at the desired wavelength.

Electrical excitation in such systems can be encouraged by means of multilayer structures. In, fact, to allow optimum electrical excitation of the Si nanograins embedded in an insulating gain medium (SiO₂), the former must have a sufficient density to be separated from one another by a distance of less than the “tunnel distance” (around 2 to 4 nm) for electron injection. In addition, these nanograins must have a size of less than around 5-6 nm and be surrounded by an oxide to conserve this quantum confinement property of the carriers which allows then to perform their role of effective sensitizer towards the rare earth ion located in their immediate proximity, the optimum distance for interaction being less than 1 nm n.

The reactive magnetron sputtering technique used to deposit these multilayers is shown in diagrammatic form in FIG. 5. It makes it possible to control the thicknesses of the different types of layers deposited as well as the location of the rare earth ion to optimize its emission. It is characterized by two aspects, the technical aspect linked to the use of two cathodes (50a and 50b) and alternating depositions by sequential rotation of the substrate-holder (anode 51) and the reactive aspect linked to the presence of hydrogen in the plasma and therefore interacting with the silica target. The two targets are made from silica and one is surmounted by a variable number of rare earth oxide wafers (52) so as to modulate the concentration of rare earth ions it includes.

The deposition sequence is as follows:
when the substrate (or the anode) is facing the target surmounted by the pieces of rare earth oxides (POSITION B), the deposition is carried out under argon plasma mixed with hydrogen (˜1:1) (53). Bearing in mind the reducing power of hydrogen with regard to the oxygen coming from the silica target, the deposited layer then contains an excess of silicon next to the rare earth ions incorporated by co-sputtering of oxide wafers.
the deposition of the SiO₂ layer is carried out by placing the substrate opposite the pure silica target (POSITION A) under a pure argon plasma (54).

These sequences are repeated as many times as necessary to obtain the required structural characteristics and optical properties for the produced film.

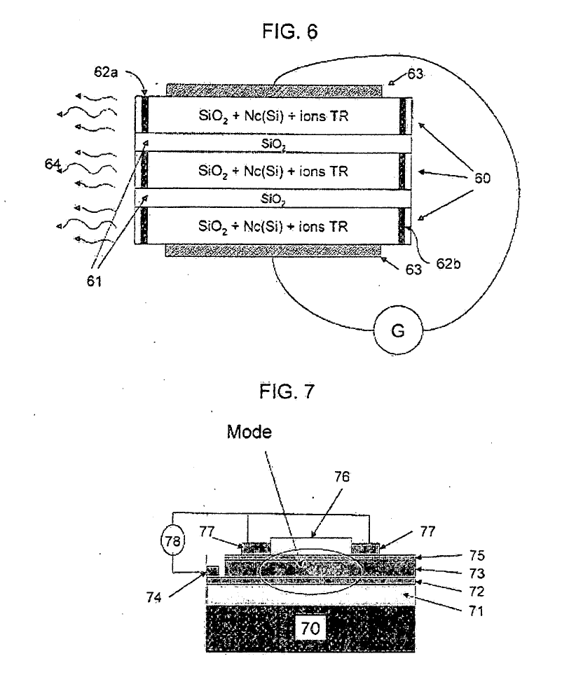

FIG. 6 shows a multilayer structure in which three layers 60 co-doped with Si nanograins and rare earth ions are separated by two insulating silicon oxide layers 61. Bragg gratings 62 are inscribed in each of the two outer layers to form the optical cavity of a laser. The electrodes 63 are placed on either side of the multilayer active medium and powered by a current generator G which runs a current through the stack of layers. The gratings 62a of one side of the structure (left side in the figure) are semi-reflecting; those 62b on the other side of the structure are almost-perfect mirrors. In this way, the light emission 64 from the laser structure excited by the circulating electrical current is carried out on the same side (left side in the figure).

FIG. 7 shows another structure in which the specific features associated with the electrodes can be combined overall or partially with the structure of FIG. 6.

The deposition of various layers of this structure is carried out by reactive magnetron sputtering methods as previously described.

The structure is deposited in layers on a silicon substrate (70). It comprises in the following order:
a first intermediate layer (buffer) 71 made from silica SiO₂ with a thickness of around 5 μm and a medium index substantially equal to 1.45;
a transparent conductive layer of ITO (indium-tin-oxide) 72 with a thickness of less than 100 nm and an index approximately equal to 1.9;
the active medium 73 comprising a layer co-doped with silicon nanograins and rare earth ions, with a thickness comprised between 500 nm and 1 μm and an index comprised between 1.5 and 2. A multilayer structure as described in reference to FIG. 6 can also be provided;

one or several metal terminals 74 on a part of the layer 72 not covered by the active medium 73, preferably on a side of the active medium other than that acting as the laser outlet (typically the side equipped with a partially reflecting Bragg mirror). This terminal 74 can be deposited either by removing part of the active medium 73 from the ITO layer or when the deposition of the active medium 73 is initially only planned for a single part of the ITO layer 72, by localized deposition of metal;
a second transparent ITO conductive layer 75 on the active medium 73, having characteristics similar to the first ITO layer 72;
a second intermediate layer of silica SiO₂ 76 with an approximate thickness of 200 nm and a medium index of around 1.45. This layer is deposited on only one part of the ITO layer 75;
one or several metal terminals 76 in direct contact with the second ITO layer 75.

The metal terminal or terminals 74 in contact with the first ITO layer 72 are connected to a terminal of a current generator 78 and the metal terminals 77 in contact with the second ITO layer 75 are connected to the other terminal of the current generator 78 so as to run a current through the active medium 73 thanks to the conductivity of the ITO layers 72 and 75. In this aspect, each ITO layer and metal terminal assembly is considered to be an electrode of the electrically excitable laser.

This causes a distribution of photons (resulting from de-excitation of the rare earth ions causing the laser phenomenon) inside the guide formed by the active medium.

This structure has the advantage of overcoming the potential barrier induced by the presence of the intermediate silica layer between the substrate and the active layer.

To guarantee the guiding of the light in the active medium (amplification medium) a lower index is used on either side of the guide (layers 71 and 76 with index 1.45 against a minimum of 1.5 for the active layer 73). To reduce the impact of the transparent conductive ITO layers 72 and 75 on guiding and amplifying the light signal and, in particular, to avoid losses due to evanescent waves, the transparent layers are chosen to be thin, of the order of several tens of nm. In addition, these layers potentially represent a potential barrier to overcome for the charge carriers. Thus, the layer is possibly extremely thin, of the order of several nm to 10 nm.

The following rare earths can benefit from the role of effective sensitizer played by the Si nanograins:
The Yb³⁺ ion for an emission at around 1 μm.
The Er³⁺ ion for an emission at 1.54 μm which therefore allows optical transport and transfer of information, in particular in computers.
The Tm³⁺ ion for an emission close to 2 μm for applications including telemetry, eyepiece safety, in the medical field.
The Ho³⁺ ion also for an emission at around 2 μn and therefore for the same fields of application as the Tm³⁺ ion.

Furthermore, different types of gain media can be used:
silicon dioxide SiO₂;
silicon oxides SiOₓ;
silicon oxynitrides SiOₓN_{y}.

For the silicon oxynitride gain media, it is possible for the plasma to be enriched with nitrogen, thus making it possible to form an oxynitride gain medium which encourages electrical conduction within it in the presence of Si nanograins. The presence of nitrogen can complement that of hydrogen.

1. A laser amplification structure comprising an active medium and at least two electrodes disposed on either side of said active medium, said active medium comprising a first layer of a silicon oxide doped with rare earth ions, wherein said first silicon layer is co-doped with silicon nanograins and rare earth ions.

2. The structure according to claim 1, wherein said active medium further comprises a thin layer of silicon oxide not doped with rare earth ions on which said first layer is deposited.

3. The structure according to claim 2 wherein the active medium comprises a plurality of layers of a silicon oxide co-doped with silicon nanograins and rare earth ions, said co-doped layers being separated by layers of non-doped silicon oxide, top and bottom layers of said active medium being co-doped layers.

4. The structure according to claim 1, wherein said co-doped layer has a structure in which the average distance separating a rare earth ion from a nanograin of silicon in said active medium is less than or equal to 0.4 nm.

5. The structure according to claim 1, wherein the rare earth ions are of at least one selected from the group consisting of Nd³⁺, Yb³⁺, Er³⁺, Tm³⁺ and Ho³⁺.

6. The structure according to claim 1, wherein said active medium comprises Bragg gratings disposed substantially perpendicular to said electrodes, said gratings being made from germanium Ge ions photoinscribed in said co-doped layer(s).

7. The structure according to claim 1 wherein said electrodes each comprise a conductive layer adjacent respectively to one of the opposing faces of the active medium.

8. The structure according to claim 4, wherein said co-doped layer(s) is(are) thin layers.

9. An optical laser comprising an optical cavity equipped with an amplification structure according to claim 1 and an electric current generator connected to said electrodes.

10. The laser according to claim 9, wherein said current generator is arranged, when in use, to run an electric current through said active medium to excite said silicon nanograins.

11. A method of manufacturing a laser amplification structure, comprising:
depositing an active medium including depositing a layer of a silicon oxide co-doped with silicon nanograins and rare earth ions on a substrate, and
depositing electrodes on either side of the active medium.

12. The method according to claim 11, wherein an electrode is deposited prior to depositing the active medium by depositing a conductive layer on said substrate, and depositing a second electrode after depositing the active medium on the opposite surface of the active medium.

13. The method according to claim 11, wherein depositing the active medium is carried out by reactive magnetron co-sputtering of at least one target comprising a first silicon oxide material and a second rare earth material, said second material being arranged on one part of said target.

14. The method according to claim 13, wherein said at least one target is a single silicon oxide target surmounted by a plurality of rare earth oxide wafers.

15. The method according to claim 13 wherein the surface of the target taken up by said rare earth material is comprises between 3% and 30% of the total surface of said single target.

16. The method according to claim 13, wherein said at least one target comprises a silicon Si target, a target of said first silicon oxide SiO₂ material and a target of said second rare earth material.

17. The method according to claim 13 wherein said co-sputtering step is carried out in a vacuum enclosure comprising ionized argon and hydrogen plasmas.

18. The method according to the preceding claim, wherein the hydrogen rate in the plasma is comprises between 40% and 90%.

19. The method according to claim 13 to 18, wherein during said co-sputtering, said target is also surmounted by at least one wafer comprising Ge.

20. The method according to claim 11, further comprising annealing said layer thus formed at a temperature between 800 and 1100° C. during at least ten minutes.

21. The method according to claim 11, wherein depositing the active medium comprises the following succession:
depositing a co-doped layer, and
a subsequent deposition step for forming a layer of non-doped silicon oxide on said co-doped layer.

22. The method according to the preceding claim, wherein the deposition of a co-doped layer is a step of reactive magnetron co-sputtering of at least one target comprising a first silicon oxide material and a second rare earth material, said second material being disposed on a part of said target, and
said subsequent deposition is a reactive magnetron sputtering of a silicon oxide target to form a non-doped silicon oxide layer on said co-doped layer.

23. The method according to the preceding claim, comprising a plurality of alternations of depositing co-doped layers and subsequent depositing steps multilayer structure, the first and last steps of said plurality of alternations being co-sputtering steps for depositing co-doped layers.

24. The method according to claim 22, wherein during said sputtering, the argon plasma is a pure argon plasma.

25. The method according to claim 23, wherein during said sputtering, said plasma is enriched with hydrogen.

26. The method according to claim 11, wherein the rare earth ions are at least one type selected from the group consisting of Nd³⁺, Yb³⁺, Er³⁺, Tm³⁺ and Ho³⁺.

27. In a method of a laser comprising an optical cavity equipped with a laser amplification structure and an electric current generator,
said laser amplification structure comprising an active medium and at least two electrodes disposed on either side of said active medium, said active medium comprising a first layer of a silicon oxide is co-doped with silicon nanograins and rare earth ions, and
said electric current generator is connected to said electrodes,
the step comprising running an electric current through said active medium by applying a power supply to the terminals of said electrodes.

28. (canceled)
